(19) United States
(12) Patent Application Publication
(10) Pub. No.: US 2019/0148231 A1
(43) Pub. Date: May 16, 2019

(54) MOS TRANSISTOR FOR SUPPRESSING GENERATION OF PHOTO-INDUCED LEAKAGE CURRENT IN ACTIVE CHANNEL REGION AND APPLICATION THEREOF

(71) Applicants: SUN YAT-SEN UNIVERSITY, Guangdong (CN); SUN YAT-SEN UNIVERSITY CARNEGIE MELLON UNIVERSITY SHUNDE INTERNATIONAL JOINT RESEARCH INSTITUTE, Foshan, Guangdong (CN)

(72) Inventors: Shaojun LIU, Guangdong (CN); Ke ZHANG, Guangdong (CN); Deng PENG, Guangdong (CN); Heshen WANG, Guangdong (CN); Weijing MO, Guangdong (CN); Xi LIU, Guangdong (CN); Maosen HUANG, Guangdong (CN)

(73) Assignees: SUN YAT-SEN UNIVERSITY, Guangdong (CN); SUN YAT-SEN UNIVERSITY CARNEGIE MELLON UNIVERSITY SHUNDE INTERNATIONAL JOINT RESEARCH INSTITUTE, Foshan, Guangdong (CN)

(21) Appl. No.: 16/092,763

(22) PCT Filed: May 31, 2016
(86) PCT No.: PCT/CN2016/084131

§ 371 Date: Oct. 11, 2018

(30) Foreign Application Priority Data
Apr. 12, 2016 (CN) 201610227996.9

(51) Int. Cl. H01L 21/77; H01L 27/12; H01L 29/786

(52) U.S. Cl. CPC H01L 21/77; H01L 2021/775; H01L 29/786; H01L 27/12

(57) ABSTRACT

The invention discloses a MOS transistor for suppressing generation of a photo-induced leakage current in an active channel region, and an application thereof. A fabrication process comprises: forming a source and a drain at both ends of a substrate by ion implantation, fabricating a gate oxide layer in a middle of an upper surface of the substrate; depositing a polysilicon or a metal on the gate oxide layer to form a gate; depositing an isolation layer above the gate, the source, and the drain; etching contact holes above the source and the drain to extract the source and the drain; depositing the metal on the contact holes above the source and the drain; etching the metal on the drain to isolate the source from the drain; and enabling the metal on the source to directly extend to cover the active channel region, so as to block light rays. The MOS transistor proposed by the invention effectively blocks the light rays incident from above the MOS transistor, suppresses generation of the photo-induced leakage current, not only improves off-state characteristics of the transistor, but also improves a working performance of an active address driving circuit.

### TECHNICAL FIELD

The present invention relates to a field of optoelectronic devices, and more particularly to a MOS transistor for suppressing generation of a photo-induced leakage current in an active channel region, and an application thereof.

### BACKGROUND

Addressing drive circuit has been currently used in many aspects. In addressing mechanism, there are generally two types, namely an active matrix and a passive matrix. Compared to the passive matrix, the active matrix has better controllability, reduces crosstalk, and enables a large-scale and high-resolution display. And also the active matrix has advantages of high energy utilization and achieving more gray scale for high quality display. Active matrix display has been developed for decades and has been used in applications such as an active matrix liquid crystal display, an active matrix organic light emitting diode display, and a recently developed active matrix light emitting diode display.

There are many kinds of active drive circuit, and a commonly used 2T1C drive circuit is as shown in FIG. 1, comprising an addressing transistor T1, a drive transistor T2 and a storage capacitor. A Vselect signal is used to control gating the T1 transistor. When the T1 transistor is turned on, a Vdata signal is transmitted to a gate of the T2 transistor to control gating the T2 transistor. When the T2 transistor is turned on, an anode of an LED is connected to VDD, so that the LED can work normally, that is, emits light. When a selection signal passes, the T1 transistor is turned off, but the LED is still required to continue to emit light. At this time, a storage capacitor is used to hold a potential of a point A to ensure that a sufficient current flows through the LED during an entire frame period. However, when an ambient light is present, especially when this circuit is applied to an LED display having a relatively high luminous intensity, the light will excite additional electron-hole pairs in an active channel region of a MOS transistor, causing that there is still a certain amount of reverse leakage current when the MOS transistor is turned off. When the leakage current is relatively large, a capability of the storage capacitor to hold the potential is seriously affected, thereby reducing an illumination time and an illumination quality of the corresponding LED. Similarly, an off-state leakage current of the T2 transistor will also bring about unexpected adverse effects. These will reduce an application quality and effectiveness of LED, LCD and OLED displays based on such an active drive circuit, or of an optical communication device.

### SUMMARY OF THE INVENTION

In order to overcome the phenomenon described in the prior art that a photocurrent excited by illumination causes an increase in a reverse leakage current when the MOS transistor is in an off-state, the present invention firstly provides a method for fabricating a MOS transistor for suppressing generation of a photo-induced leakage current in an active channel region.

The present invention further proposes a MOS transistor for suppressing generation of the photo-induced leakage current in the active channel region.

The present invention further proposes an active addressing circuit using the MOS transistor for suppressing generation of the photo-induced leakage current in the active channel region.

In order to solve the above technical problem, the technical solution of the present invention is as follows.

A method for fabricating a MOS transistor for suppressing generation of a photo-induced leakage current in an active channel region, a fabrication process thereof comprising: forming a source and a drain at both ends of a substrate by ion implantation; fabricating a gate oxide layer in a middle of an upper surface of the substrate; and depositing a polysilicon or a metal on the gate oxide layer to form a gate; the fabrication process further comprising: depositing an isolation layer above the gate, the source, and the drain; etching contact holes above the source and the drain to extract the source and the drain; depositing the metal in the contact holes above the source and the drain; etching the metal in the contact holes on the drain to isolate the source from the drain; and enabling the metal in the contact holes on the source to directly extend to cover the active channel region, so as to block light rays.

Preferably, said substrate is a silicon substrate.

Preferably, said isolation layer is a SiO₂ isolation layer.

A MOS transistor for suppressing generation of a photo-induced leakage current in an active channel region, comprising: a substrate, a gate insulating layer deposited in a middle of an upper surface of the substrate; a gate formed by a polysilicon or a metal on the gate insulating layer; and a source and a drain that are formed at both ends of the substrate by ion implantation; an isolation layer being deposited above the gate, the source and the drain, the isolation layer above the source and the drain being etched with the contact holes for extracting the source and the drain, the metal being deposited in the contact holes on the source and the drain, the metal in the contact holes on the drain being etched with isolation notches for isolating the source and the drain, and the metal on the source directly extending to cover the active channel region.

Preferably, said substrate is a silicon substrate.

Preferably, said isolation layer is a SiO₂ isolation layer.

An active addressing circuit applying said MOS transistor for suppressing generation of the photo-induced leakage current in the active channel region, the MOS transistor in said active addressing circuit is a MOS transistor that suppresses generation of the photo-induced leakage current in the active channel region.

Compared with the prior art, the technical solution of the present invention has following beneficial effects: the MOS transistor proposed by the invention effectively blocks the light rays, suppresses the generation of the photocurrent, improves the off-state characteristics of the transistor, and improves the performance of the active addressing drive circuit.

### BRIEF DESCRIPTION OF THE DRAWINGS

FIG. 1 is a schematic diagram of a 2T1C active drive circuit.

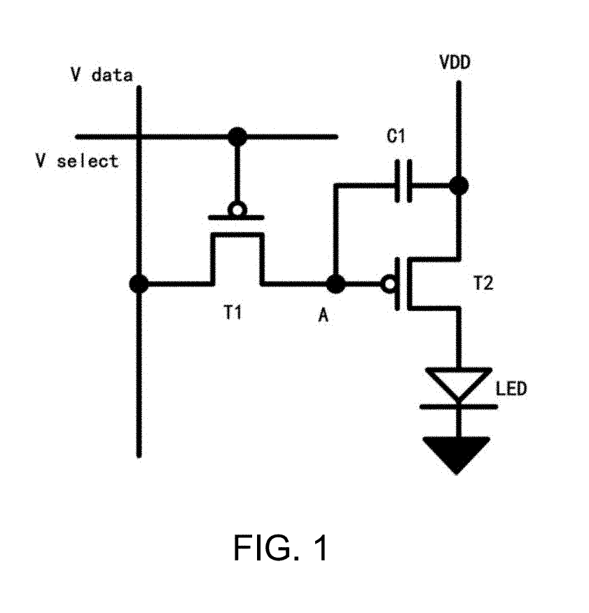

FIG. 2 is a comparison diagram of transfer characteristics curves of a transistor under different conditions.

FIG. 3 is a cross-sectional schematic view of a conventional MOS transistor.

FIG. 4 is a three-dimensional structural view of the MOS transistor according to the present invention.

FIG. 5 is a planar structural schematic view of the MOS transistor according to the present invention.

FIG. 6 is a schematic diagram showing a setting of simulation basic parameters for simulating the MOS transistor according to the present invention.

FIG. 7 is a curve diagram showing transfer characteristics of a PMOS transistor in different lengths X according to the present invention.

FIG. 8 is a PCB layout of an active addressing circuit that automatically eliminates a photo-induced leakage current.

FIG. 9 is a comparison diagram in charging and discharging of a storage capacitor in an active drive circuit according to an embodiment.

FIG. 10 is a PCB layout of MOS transistors in different lengths X and different number of finger gates.

FIG. 11 is a comparison schematic diagram of transfer characteristics curves according to FIG. 10.

### DETAILED DESCRIPTION OF THE INVENTION

The accompanying drawings are for illustrative purposes only and are not to be considered as limiting of the invention. In order to better illustrate the embodiments, some parts of the accompanying drawings may be omitted, enlarged or reduced, and do not represent dimensions of an actual product;

It will be apparent to those skilled in the art that certain known structures and their description may be omitted. The technical solution of the present invention will be further described below with reference to the accompanying drawings and embodiments.

In view of the phenomenon mentioned in the prior art that a photocurrent excited by illumination causes an increase in a reverse leakage current when the MOS transistor is in an off-state, the present invention proposes to extend a certain length of metal from a source of a MOS transistor to cover an active channel region of the MOS transistor, so as to achieve an effect that light rays are prevented from being directly incident a channel.

This design effectively blocks the light rays and suppresses generation of the photocurrent, which not only improves off-state characteristics of the transistor, but also improves a performance of an active addressing drive circuit. The longer a metal coating, the better a suppression effect, but it will reduce a channel width-to-length ratio of a device, thus reducing characteristics of the device when it is on-state. Therefore, appropriate trade-offs should be made between the coating and the channel width-to-length ratio to achieve an optimal design.

After a lot of experiments and researches, it is found that illumination affects the performance of the MOS transistor.

Illumination excites additional electron-hole pairs in the active channel region of the MOS transistor, resulting in a relatively large reverse leakage current when the transistor is turned off. This idea is verified through software simulation.

In the absence of light, in the case of blue, red, and green illumination, we tested I_{ds} of a PMOS transistor with a channel length of 2 μm. An illumination power is 1 w, and V_{ds} is set to −1V, a gate voltage is gradually increased from −5V to 5V, and a threshold voltage is −0.5V, that is, it is in the off-state when the threshold voltage is greater than −0.5V.

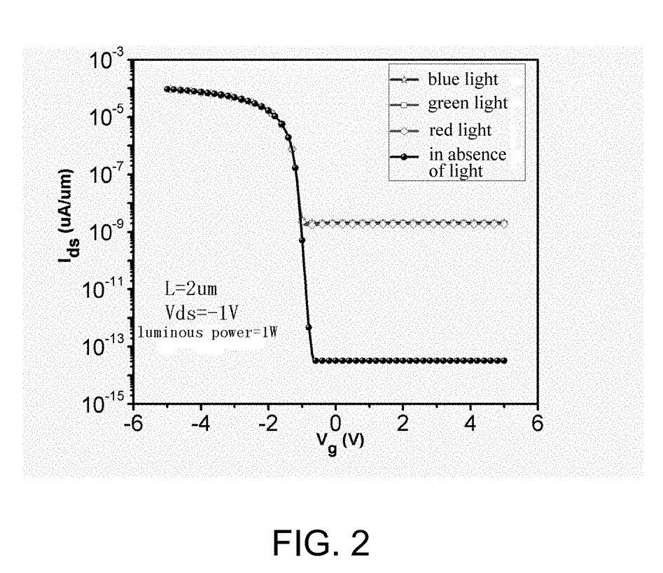

FIG. 2 shows a comparison of transfer characteristics of the transistor under different conditions, from which a performance difference of the MOS transistor under illumination conditions can be seen. It can be clearly seen from the figure that the leakage current in the off-state under a light condition is several orders of magnitude larger than that in the absence of light condition, and it can be seen that an impact of illumination on the performance of the MOS transistor is still very huge. This proves our idea that the illumination condition does have a huge impact on the leakage current when the MOS transistor is in the off-state.

Based on the above findings, the present invention devises a novel MOS transistor structure capable of blocking illumination and suppressing generation of the photo-induced leakage current in an active channel region.

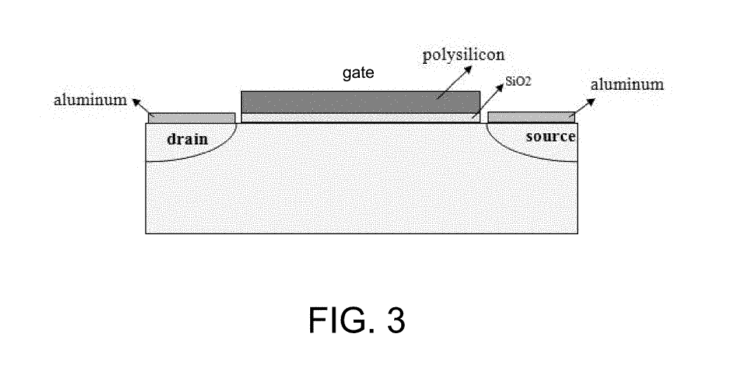

Conventional MOS transistor uses a doping process to form a source and a drain at both ends of a silicon substrate, and the source and the drain are extracted by depositing a metal and appropriately etching. Thereafter, a gate oxide layer is deposited above the active channel region, and a polysilicon is deposited thereon to form a gate. The cross-sectional view is shown in FIG. 3.

However, the main difference between the novel structure proposed by the present invention and the conventional one is that the metal portion of the source extends a certain length and covers the active channel region, thereby preventing the active channel region from being directly exposed to the illumination to generate an excess photocurrent. A specific practice is as follows.

A method for fabricating a MOS transistor for suppressing generation of a photo-induced leakage current in an active channel region, the fabrication process thereof comprising: forming a source and a drain at both ends of a substrate by ion implantation; fabricating a gate oxide layer in a middle of an upper surface of the substrate; and depositing a polysilicon or a metal on the gate oxide layer to form a gate; depositing an isolation layer above the gate, the source, and the drain; etching contact holes above the source and the drain to extract the source and the drain; depositing the metal on the contact holes above the source and the drain; etching the metal on the drain to isolate the source from the drain; and enabling the metal on the source to directly extend to cover the active channel region, so as to block light rays.

The MOS transistor for suppressing generation of the photo-induced leakage current in the active channel region that is fabricated by the above-described method, comprises: a substrate, a gate insulating layer deposited in a middle of an upper surface of the substrate; a gate formed by a polysilicon or a metal on the gate insulating layer; and a source and a drain formed at both ends of the substrate by ion implantation; the isolation layer being deposited above the gate, the source and the drain, the isolation layer above the source and the drain being etched with contact holes for extracting the source and the drain, the metal being deposited in the contact holes on the source and the drain, the metal in the contact holes on the drain being etched with isolation notches for isolating the source and the drain, and the metal on the source directly extending to cover the active channel region.

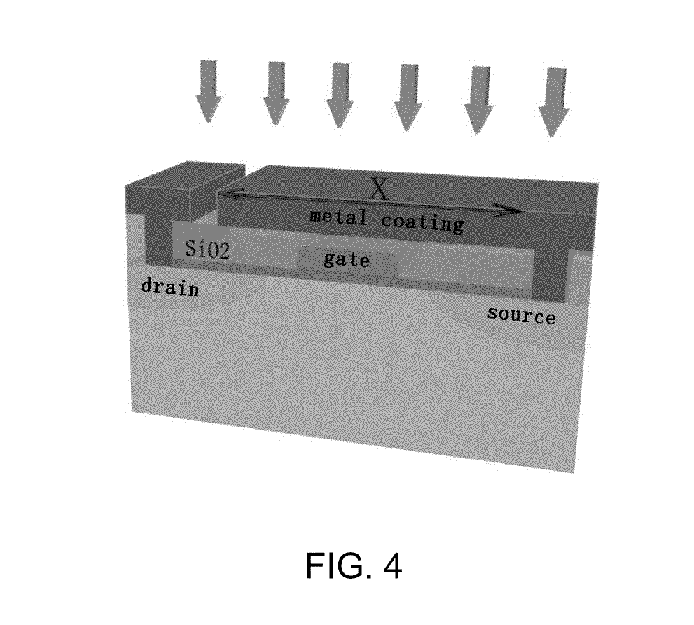

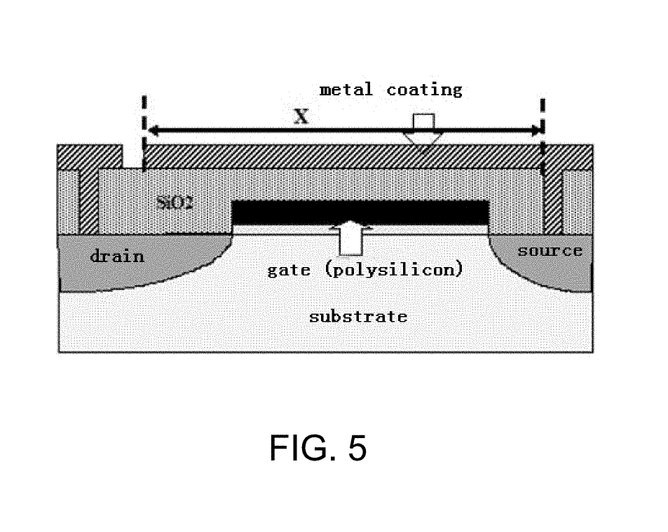

Such structure does not add other excess materials to cause unpredictable other performance changes, and further achieves a good effect of blocking light, and is simple and easy to implement. The specific three-dimensional, planar structure diagrams are shown in FIGS. 4 and 5, wherein an arrow indicates a direction of illumination and X indicates a length of a metal coating.

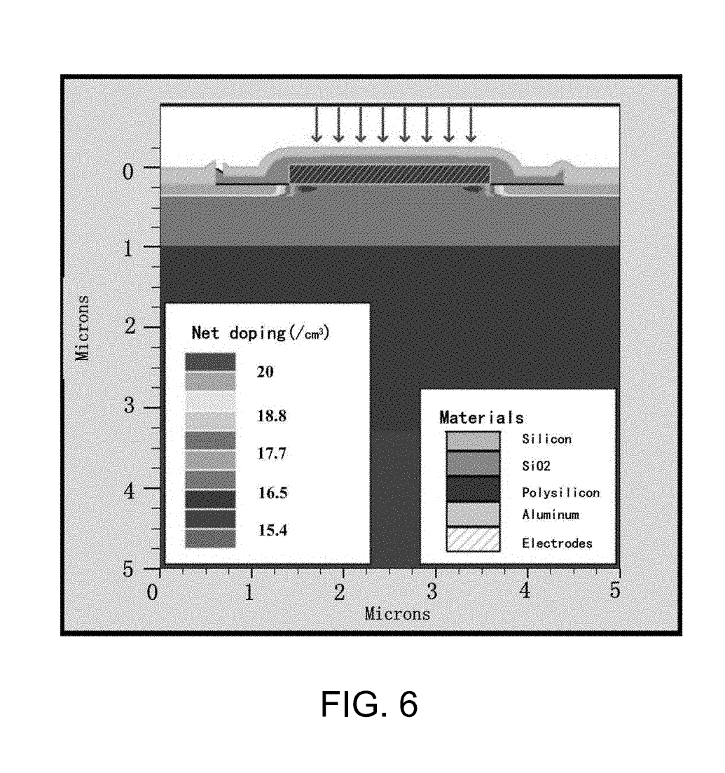

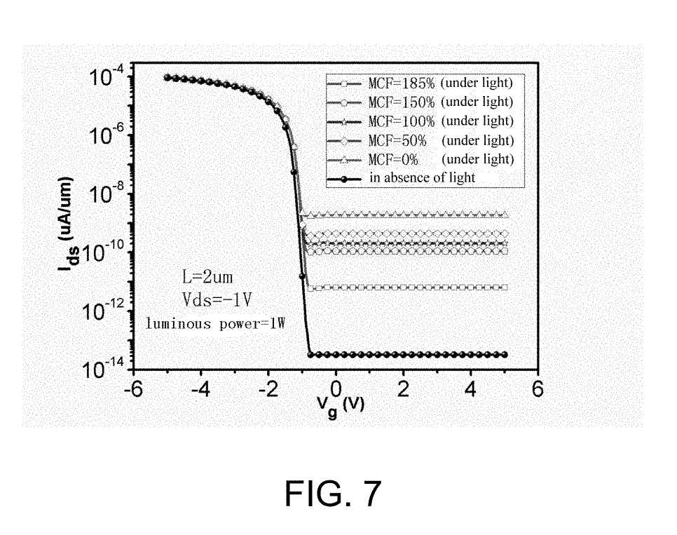

In order to prove the effectiveness of this MOS transistor structure, the present embodiment is simulated by software, and basic parameters of the simulation are as shown in FIG. 6. The transistor adopts a silicon substrate, a phosphorus-doped PMOS, and a SiO2 layer and a metal portion are deposited thereon by a semiconductor process. During the simulation, V_{GS} is gradually increased from −5V to 5V, V_{DS} is set to −1V, and the PMOS transistor is illuminated with 1 w power and 625 nm wavelength illumination. The transfer characteristics curves of the PMOS transistor are as shown in FIG. 7.

Wherein, MCF (Metal Cover Factor) is a ratio of the length of the metal coating to a channel length, namely:

$$M C F = \frac{X}{L} \times 100 \%$$

As a reference index with more reference significance, this parameter more vividly shows a relationship between the length of the coating and the length of the active channel. It can be seen from FIG. 7 that under in the absence of light condition, the leakage current is 2.5×10⁻¹³ A, when there is no metal coating but illumination (MCF=0%), and the leakage current is about 1×10⁻⁸ A, which is increased by several orders of magnitude. When there is a certain length of the metal coating, the photocurrent excited under illumination is significantly reduced, and the higher the MCF index, the better the photocurrent suppression effect. It is indicated that the present invention can effectively eliminate the influence of the photocurrent and improve performance of the transistor.

In this embodiment, the active addressing circuit capable of automatically eliminating the photo-induced leakage current is further designed.

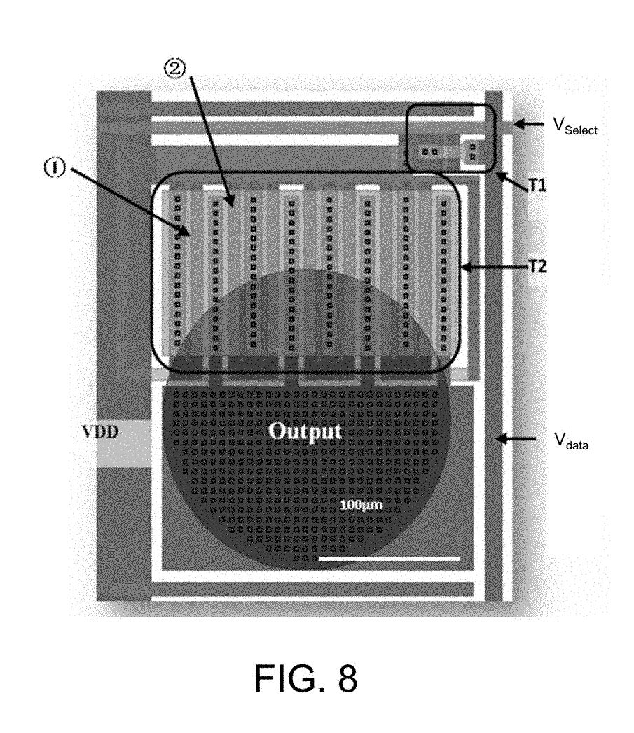

This embodiment is based on the conventional 2T1C circuit that is introduced in the BACKGROUND section. In this circuit, T1 is an addressing transistor, T2 is a drive transistor, and C is a storage capacitor. Vselect is a selection signal, which controls turn-on and turn-off of the T1 transistor, and Vdata is a data signal, which carries a signal that controls on and off of the LED. In this example, the active addressing circuit that automatically eliminates the photo-induced leakage current is designed based on the proposed new MOS. Its layout is shown in FIG. 8:

FIG. 8 shows the 2T1C circuit layout in a simplified manner. For the transistor T2, an elongated region indicated by \textcircled{1} is a finger gate, and below it at \textcircled{2} is the metal coating. Similarly, a structure of the T1 transistor can be understood. In this circuit structure, the storage capacitor is composed of two portions. The first portion is composed of a SiO2 passivation layer sandwiched between the source metal and the polysilicon. The second portion is composed of a gate insulator (usually SiO2 or a high-k material) sandwiched between the polysilicon and an active single crystal silicon layer. An LED pixel can be connected with an output portion.

This circuit structure can successfully eliminate the influence of the photocurrent, and the structure is simple and easy to implement. Below we will demonstrate the enhancement of the capacitor's capability to hold potential by calculation and comparison.

We discuss it in two ways, respectively. A writing period represents a period in which the T1 transistor is gated and the data signal reaches the T2 gate through T1, and at this time, it is a charging portion for the capacitor. A holding period represents that the selection signal has passed, and the T1 transistor is turned off but the LED is still required to be illuminated, and at this time, the T2 transistor is driven mainly by the potential held by the capacitor. If there is a leakage current, the capacitor will show a gradual discharge.

Let V_{D} stand for Vdata. When a pixel is selected, a writing voltage and a holding voltage satisfy:

$${V}_{write} = {V}_{D} ( 1 - {e}^{- \frac{t}{{τ}_{on}}} )$$

$${V}_{hold} = {V}_{D} {e}^{- \frac{t}{{τ}_{off}}}$$

wherein, τₒₙ=RₒₙC_{holding} τ_{off}=R_{off}C_{holding}

Rₒₙ and R_{off} are channel resistances of the T1 transistor when the T1 transistor is turned on and turned off, respectively. The normal operation of the circuit requires:

$${V}_{signal} > 0.99 {V}_{D} ⇒ {T}_{writing} > 4.6 {τ}_{on}$$

$${V}_{signal} > 0.95 {V}_{D} ⇒ {T}_{holding} < \frac{{τ}_{off}}{19.5}$$

wherein, V_{signal} is a voltage at point A. T_{writing} and T_{holding} are the time of the writing period and the time of the holding period, respectively. This means that, the shorter the time of the writing period, the longer the time of the holding period, the better the effect of the drive circuit.

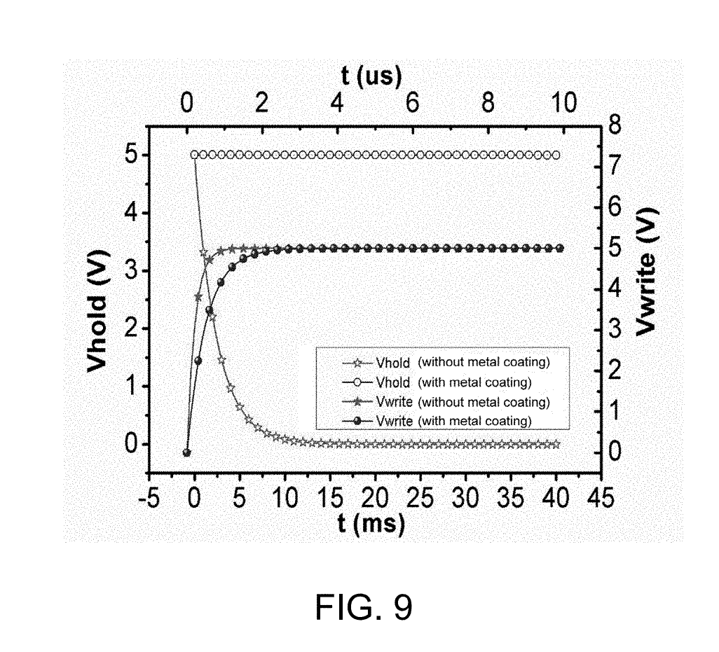

We have experimentally measured an on-state current I_{ds} of the transistor with the metal coating and without the metal coating, which is 2.75×10⁻⁵ A and 3.11×10⁻⁵ A respectively, an off-state current I_{ds} is 3.43×10⁻¹³ A and 6.94×10⁻⁹ A, respectively, and a total capacitance used in the experiment is 15.6 pf. Finally, the comparison of the charging and discharging of the storage capacitor before and after the design is applied is shown in FIG. 9.

As can be seen from FIG. 9, the design of the metal coating has little effect on charging time and may cause several μs delays. However, when the MOS transistor is in the off-state, the addition of the metal coating obviously makes the potential of the storage capacitor held longer, that is, more than 40 ms. If there is no metal coating, the potential can only be held for a few ms, far from meeting requirements for holding the LED's normal operation throughout the cycle. This shows that this design can enhance the capability of the storage capacitor to hold the potential in the circuit, thereby improving the performance of the circuit.

The present invention proposes the novel MOS transistor structure and circuit structure capable of eliminating the influence of photocurrent. As the longer the metal coating, the better the suppression effect, but therefore the greater the distance between the drain and the gate of the device. Especially when the layout has a limited area, this structure will affect the original layout, and will even directly affect the width-to-length ratio of the device and cause degradation in other performance. Therefore, appropriate trade-offs should be made between the coating and the channel width-to-length ratio to achieve an optimal design.

The distance of a fracture from the source to the drain is defined as the length of the coating (portion X), and the effects of different lengths of the coating are verified by analytical simulation.

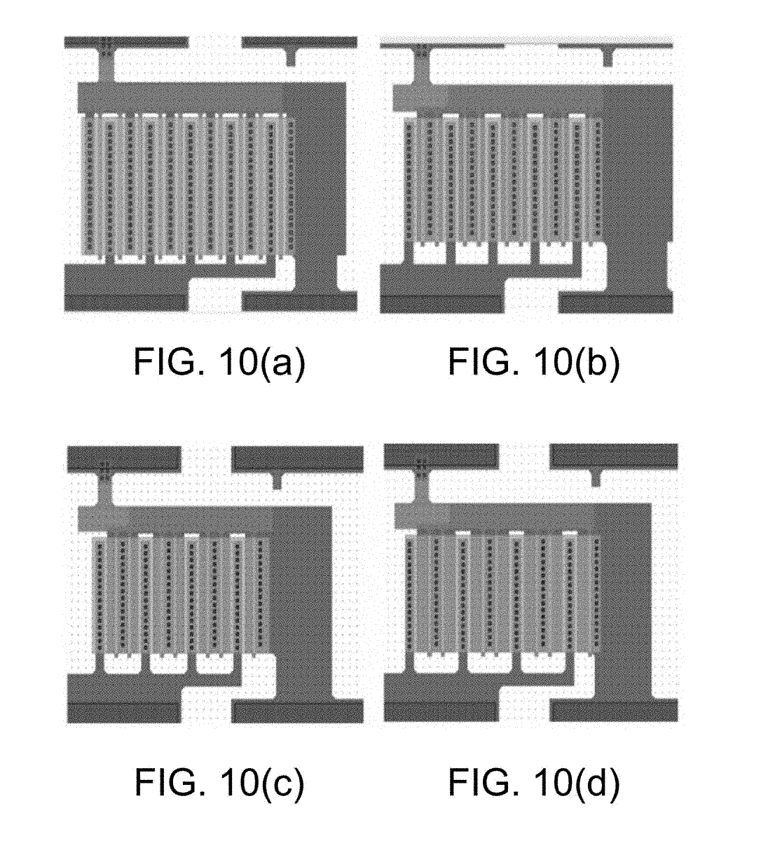

The invention achieves an optimal result by designing a plurality of sets of MOS transistors with different lengths X and number of finger gates, takes several sets of data as shown in FIG. 10 and Table 1 as an example, and finally determines that the performance of the device is the best when the number of finger gates is 9 and the metal coating length is 5 μm.

TABLE 1

| Model | length of metal | number of finger | width-to-length |
|---|---|---|---|
| number | coating (μm) | gates | ratio (μm/μm) |
| (a) | 0 | 10 | 1380/5 |
| (b) | 5 | 9 | 1242/5 |
| (c) | 10 | 7 | 966/5 |
| (d) | 15 | 7 | 966/5 |

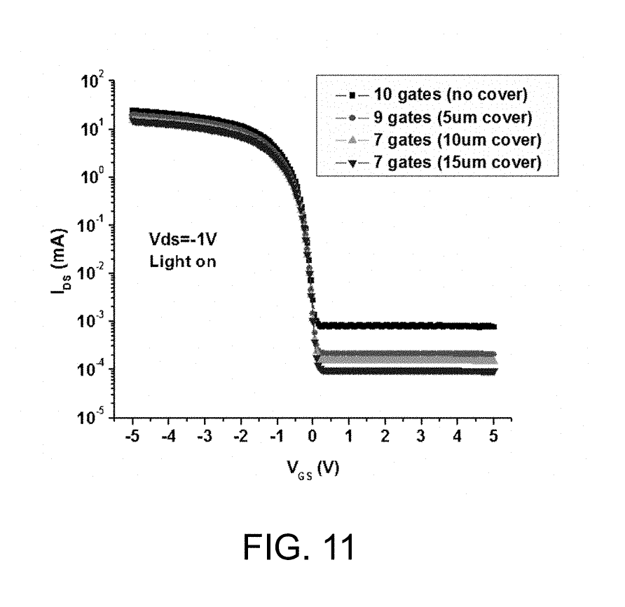

A comparison of the transfer characteristics curves is shown in FIG. 11.

From this, it can be seen that the structure has the best performance when the number of the finger gates is 9 and the length of the metal coating is 5 μm.

The transistor with this structure shown in this solution can effectively prevent the active channel region from being directly exposed to light and eliminate unnecessary photocurrent. The active addressing circuit structure based on this can further effectively eliminate the phenomenon of the photo-induced leakage current. At this time, the MOS transistor will have better off-state characteristics, the effect of the storage capacitor holding potential in the drive circuit will be better, the circuit performance will be more stable, and the LED will exhibit better working performance.

It is apparent that the above-described embodiments of the present invention are merely illustrative of the present invention and are not intended to limit the embodiments of the present invention. Other variations or modifications of the various forms may be made by those skilled in the art according to the above description. There is no need and difficult to exhaust all of the implementations. Any modifications, equivalent substitutions and improvements made within the spirit and scope of the invention are intended to be included within the scope of the appended claims of the present invention.

1. A method for fabricating a MOS transistor for suppressing generation of a photo-induced leakage current in an active channel region, a fabrication process thereof comprises: forming a source and a drain at both ends of a substrate by ion implantation; fabricating a gate oxide layer in a middle of an upper surface of the substrate; and depositing a polysilicon or a metal on the gate oxide layer to form a gate; wherein the fabrication process further comprises: depositing an isolation layer above the gate, the source, and the drain; etching contact holes above the source and the drain to extract the source and the drain, depositing the metal in the contact holes above the source and the drain; etching the metal in the contact holes on the drain to isolate the source from the drain; and enabling the metal in the contact holes on the source to directly extend to cover the active channel region, so as to block light rays.

2. The method for fabricating the MOS transistor for suppressing generation of the photo-induced leakage current in the active channel region according to claim 1, wherein the substrate is a silicon-based material substrate, a glass quartz substrate or a nitride substrate.

3. The method for fabricating the MOS transistor for suppressing generation of the photo-induced leakage current in the active channel region according to claim 1, wherein the gate oxide layer is an oxide selected from SiO₂, HfO, Al2O3 and ZrO, and the isolation layer is a SiO₂ or SiNx isolation layer.

4. A MOS transistor for suppressing generation of a photo-induced leakage current in an active channel region, comprising: a substrate; a gate insulating layer deposited in a middle of an upper surface of the substrate; a gate formed by a polysilicon or a metal on the gate insulating layer; and a source and a drain that are formed at both ends of the substrate by ion implantation; wherein an isolation layer is deposited above the gate, the source and the drain, the isolation layer above the source and the drain is etched with contact holes for extracting the source and the drain; the metal is deposited in the contact holes on the source and the drain, the metal in the contact holes on the drain is etched with isolation notches for isolating the source from the drain, and the metal on the source directly extends to cover the active channel region.

5. The MOS transistor for suppressing generation of the photo-induced leakage current in the active channel region according to claim 4, wherein the substrate is a silicon-based material substrate, a glass quartz substrate or a nitride substrate.

6. The MOS transistor for suppressing generation of the photo-induced leakage current in the active channel region according to claim 4, wherein the gate oxide layer is an oxide selected from SiO₂, HfO, Al2O3 and ZrO, and the isolation layer is a SiO₂ or SiNx isolation layer.

7. An active addressing circuit applying the MOS transistor for suppressing generation of the photo-induced leakage current in the active channel region according to claim 4, wherein the MOS transistor in the active addressing circuit is a MOS transistor that suppresses generation of the photo-induced leakage current in the active channel region.

8. An active addressing circuit applying the MOS transistor for suppressing generation of the photo-induced leakage current in the active channel region according to claim 5, wherein the MOS transistor in the active addressing circuit is a MOS transistor that suppresses generation of the photo-induced leakage current in the active channel region.

9. An active addressing circuit applying the MOS transistor for suppressing generation of the photo-induced leakage current in the active channel region according to claim 6, wherein the MOS transistor in the active addressing circuit is a MOS transistor that suppresses generation of the photo-induced leakage current in the active channel region.
